(19) United States
(12) Patent Application Publication
(10) Pub. No.: US 2016/0189841 A1
(43) Pub. Date: Jun. 30, 2016

(54) COOLING SYSTEM AND METHOD FOR A MAGNETIC RESONANCE IMAGING DEVICE

(71) Applicant: GENERAL ELECTRIC COMPANY, SCHENECTADY, NY (US)

(72) Inventors: JUN LI, SHANGHAI (CN); EVANGELOS TRIFON LASKARIS, SCHENECTADY, NY (US); LONGZHI JIANG, FLORENCE, SC (US); MINFENG XU, BALLSTON, NY (US); ERNST WOLFGANG STAUTNER, NISKAYUNA, NY (US); ANBO WU, SHANGHAI (CN)

(73) Assignee: GENERAL ELECTRIC COMPANY, SCHENECTADY, NY (US)

(21) Appl. No.: 14/587,316

(22) Filed: Dec. 31, 2014

(51) Int. Cl. H01F 6/04; G01R 33/3815; G01R 33/38; F25D 3/00

(52) U.S. Cl. CPC H01F 6/04; F25D 3/00; G01R 33/3815; G01R 33/3804

(57) ABSTRACT

A cooling system for a low-cryogen superconducting magnet includes a primary cooling loop having a liquid reservoir containing a supply of liquid cryogen and a plurality of cooling tubes fluidly coupled to the liquid reservoir and in thermal communication with the superconducting magnet. The liquid cryogen is configured for circulation through the cooling tubes for providing primary cooling for the magnet for cooling the magnet to a target temperature. The cooling system also includes a thermal battery coupled to a component that is cooled to the target temperature by the primary cooling loop and is configured to be cooled by the primary cooling and to absorb heat from the at least one component during an interruption in the primary cooling to maintain the magnet at approximately the target temperature.

### BACKGROUND

1. Technical Field

Embodiments of the invention relate generally to magnetic resonance imaging and, more specifically, to a system and method for cooling a magnetic resonance imaging device.

2. Discussion of Art

Magnetic resonance imaging (MRI) machines work by generating a very large magnetic field using a superconducting magnet which consists of many coils or windings of wires through which a current is passed. Maintaining a large magnetic field requires a lot of energy, and this is accomplished using superconductivity, which involves trying to reduce the resistance in the wires to almost zero. This may be achieved by bathing the coils in a continuous supply of liquid cryogen, such as liquid helium, and/or by circulating liquid cryogen within cooling loops adjacent to, or through, the coils.

Maintaining an ultra-low temperature in the coils is necessary for proper operation of the MRI machine. During operation, however, heat may be generated from a resistance of current leads when the superconducting magnet is ramped-up or ramped-down to generate or to turn off the resulting magnetic field, which may result in boil-off or evaporation of the cryogen, requiring replenishment.

Considerable research and development efforts have therefore been directed at minimizing the need to replenish the boiling cryogen. This has led to the use of closed-loop cryogen gas recondensing systems that utilize a mechanical refrigerator or cryocooler, also known as a coldhead, to cool the cryogen gas and recondense it back to liquid cryogen for reuse.

However, from time to time it becomes necessary to remove the cryocooler for replacement and/or servicing. It is desirable to accomplish this without discontinuing superconducting operation of the magnet because of the time and expense resulting from relatively long “down-time” and subsequent ramping up period of bringing the magnet back to superconducting operation.

Replacement of the cryocooler must therefore be effected in the period after a problem or service need is detected and before superconducting operation ceases. This period is known as the ride-through period during which the final period of superconducting magnet operation and helium boil-off continues before quenching of the superconducting magnet. Indeed, for magnets with closed helium inventory, i.e., low cryogen type magnets, the duration of tolerable power outage, coldhead service or ramp profile is limited by the volume of accumulated liquid helium that boils off or evaporates during the above conditions with extra heat load. Indeed, typical conduction-cooled or thermosiphon-cooled superconducting magnets have very little cryogen storage to extend ride-through time.

It is therefore desirable to be able to extend the ride-through period for a low-cryogen superconducting magnet to provide sufficient time for detection and correction of a problem such as by replacement of a cryocooler, to withstand a power outage, and also to avoid the possibility of peak temperatures being generated by superconducting operation quench which could exceed the critical temperature of the superconducting wires with which the magnet coils are wound.

### BRIEF DESCRIPTION

In an embodiment, a cooling system for a low-cryogen superconducting magnet is provided. The cooling system includes a primary cooling loop having a liquid reservoir containing a supply of liquid cryogen and a plurality of cooling tubes fluidly coupled to the liquid reservoir and in thermal communication with the superconducting magnet. The liquid cryogen circulates through the cooling tubes to provide primary cooling for the magnet for cooling the magnet to a target temperature. The cooling system also includes a thermal battery coupled to a component that is cooled to the target temperature by the primary cooling loop and is configured to be cooled by the primary cooling and to absorb heat from the at least one component during an interruption in the primary cooling to maintain the magnet at approximately the target temperature.

In an embodiment, a cooling system for a low-cryogen superconducting magnet is provided. The system includes a primary cooling loop having a cryogen configured for circulation therethrough. The first cooling loop is in thermal communication with a cold mass and is configured to cool the cold mass to a target temperature. The cold mass includes at least one of a coil of the superconducting magnet, a support shell for supporting the coil, and a liquid reservoir containing the cryogen. The system also includes a cryocooler configured to cool the cryogen within the primary cooling loop and a thermal battery configured absorb heat from at least one component other than the cold mass and to minimize heat leak from the component to the cold mass.

In another embodiment, a method of cooling a superconducting magnet of an imaging device is provided. The method includes the step of circulating a liquid cryogen through a cooling loop in thermal communication with a cold mass including at least one of a coil of the superconducting magnet, a coil support shell and a reservoir containing the liquid cryogen to cool the cold mass to a target temperature and, at a thermal battery, absorbing heat from the cold mass via conduction between the thermal battery and the cold mass.

In yet another embodiment, a method of cooling a superconducting magnet of an imaging device is provided. The method includes the steps of circulating a liquid cryogen through a cooling loop in thermal communication with a cold mass including at least one of a coil of the superconducting magnet, a coil support shell and a reservoir containing the liquid cryogen to cool the cold mass to a target temperature, and minimizing heat leak from a component of the imaging device to the cold mass by absorbing heat from the component utilizing a thermal battery.

### DRAWINGS

The present invention will be better understood from reading the following description of non-limiting embodiments, with reference to the attached drawings, wherein below:

FIG. 1 is side, cross-sectional view of a cooling system for a magnetic resonance imaging machine in accordance with an embodiment of the present invention.

FIG. 2 is a schematic illustration of the system of FIG. 1, shown in connection with a magnetic resonance imaging machine.

FIG. 3 is a simplified block diagram of the cooling system of FIG. 1, illustrating a position of a thermal battery thereof.

FIG. 4 is a simplified block diagram of a cooling system illustrating the position of a thermal battery thereof in accordance with another embodiment of the present invention.

FIG. 5 is a simplified block diagram of a cooling system illustrating the position of a thermal battery thereof in accordance with another embodiment of the present invention.

FIG. 6 is a simplified block diagram of a cooling system illustrating the position of a thermal battery thereof in accordance with another embodiment of the present invention.

FIG. 7 is a cross-sectional plan view illustrating a thermal battery cooling arrangement for the cooling system of FIG. 6.

FIG. 8 is a cross-sectional end view illustrating a thermal battery cooling arrangement for the cooling system of FIG. 6.

### DETAILED DESCRIPTION

Reference will be made below in detail to exemplary embodiments of the invention, examples of which are illustrated in the accompanying drawings. Wherever possible, the same reference characters used throughout the drawings refer to the same or like parts. Although embodiments of the present invention are described as intended for use with superconducting magnets embodied in MRI machines, the present invention may also be used for the cooling of superconducting magnets, generally, irrespective of their specific end use. As used herein, “thermally interconnected,” “thermally connected” and “thermal communication” means that two physical systems or components are associated in such a manner that thermal energy and heat may be transferred between such systems or components. For example, such thermal communication can be achieved, without loss of generality, by snug contact between surfaces at an interface; one or more heat transfer materials or devices between surfaces; a connection between solid surfaces using a thermally conductive material system, or other structures with high thermal conductivity between the surfaces (e.g., heat exchangers); other suitable structures; or combinations of structures. Substantial thermal communication can take place between surfaces that are directly connected (e.g., contact each other) or indirectly connected via one or more interface materials. Thermal communication be conductive, convective, radiative, or any combination thereof. As also used herein, “fluid communication” or “fluidly coupled” is meant to refer to a coupling through a channel or conduit that allows fluids (e.g., gases and liquids) to flow therethrough or therebetween, at least at desired times. As used herein, “ride-through” means an operating state where cooling power has been interrupted but the superconducting magnet is maintained safely energized at low temperature without quench.

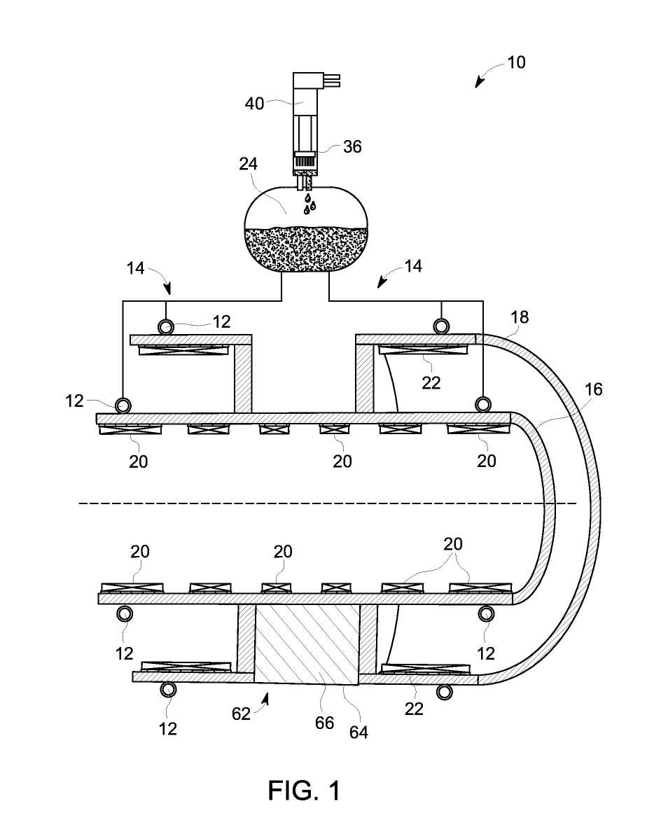

Referring now to FIG. 1, a cooling system 10 for a superconducting magnet of a MRI machine is illustrated. As shown therein, the cooling system 10 includes a plurality of cooling tubes 12, or other suitable cooing paths, with liquid helium circulating within the cooling tubes 12. The cooling tubes 12 define a primary cooling loop 14. The cooling tubes 12 are thermally coupled to a main former or support shell 16 and, in an embodiment, may also be thermally coupled to a shield former or support shell 18 that encompasses the main former 16. The main former 16 and shield former 18 support or maintain the position of main MRI magnet coils 20 and shielding MRI magnet coils 22 (also referred to as bucking coils), respectively, in a manner heretofore known in the art. For example, the main magnet coils 20 may be shrink fit and bonded inside the main former 16, which may be a cylindrical metal coil former, to thereby provide thermal contact therebetween. Likewise the shield magnet coils 22 may be shrink fit and bonded inside the shield former 18, which may be a cylindrical metal coil former, to thereby provide thermal contact therebetween. Other types of coils may be provided, for example, epoxied coils. In an embodiment the main magnet coils 20 and the magnet shielding coils 22 may be formed from any material capable of producing a superconducting magnet, such as from Niobium-titanium (NbTi), Niobium-tin (Nb₃Sn) or Magnesium-di-boride (MgB₂).

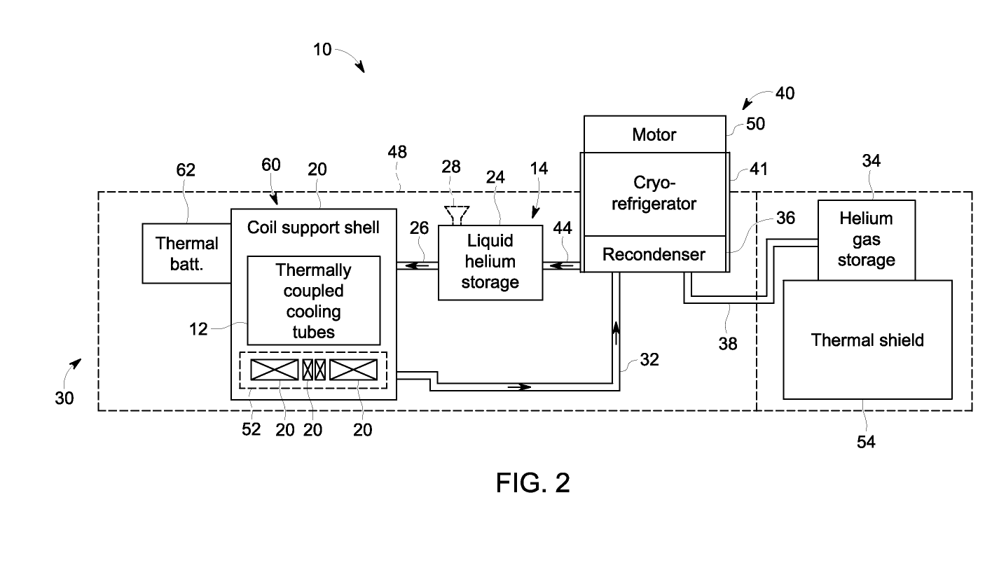

As further illustrated in FIG. 2, the various embodiments of the present invention may be implemented as part of an MRI magnet system 30, such as those commonly known in the art, wherein the cooling may be provided via a two stage cooling arrangement. It should be noted that like numerals represent like parts throughout the Figures.

The coil formers 16, 18, which may be formed from a thermally conductive material (e.g., aluminum), provide a cold mass support structure that maintain the position of or support the magnetic coils 20, 22, respectively (shielding magnet coils 22 not shown in FIG. 2). The cooling tubes 12, which may be formed from any suitable metal (e.g., copper, stainless steel, aluminum, etc.) are in fluid communication with a primary, or first, liquid cryogen storage tank 24. The cryogen storage tank 24 contains a first liquid cryogen used in the closed loop cooling system 10 to cool the cold mass 60, including magnet coils 20, 22. In an embodiment, the cryogen is liquid helium. The fluid communication between the cooling tubes 12 and the liquid helium storage tank(s) 24 may be provided by one or more fluid passageways 26 (e.g., fluid tubes, conduits, etc.). Thus, the storage tank 24 provides the liquid helium that flows through the cooling tubes 12 to cool the magnet coils 20, 22.

Collectively, the assembly of magnet coils 20 and/or 22, the coil formers/support structure 16 and/or 18 and the cryogen reservoir 24 form a cold mass 60. As discussed in detail below, this cold mass 60 is cooled to target temperature. As used herein, “target temperature” means a cryogenic temperature sufficient to enable superconducting operation. In an embodiment, the target temperature is approximately 4 K. As used herein “cold mass” means any structure that is cooled to the target temperature during normal operation via the primary cooling loop 14.

In the illustrated embodiment, the primary cooling loop 14 contains no venting. However, in some embodiments, venting may be provided, for example, using a vent 28 having a very high venting pressure level. For example, in some embodiments the vent 28 is configured to provide venting at the highest pressure the system can handle without failure (or within a predefined range thereof). However, different pressure levels may be provided in embodiments that include the vent 28, which may be based on system requirements, regulatory requirements, etc.

As best illustrated in FIG. 2, in an embodiment, the cooling tubes 12 may be in fluid communication with a vapor return manifold or passageway 32, which may be in fluid communication with a helium gas storage system having a decoupled gaseous helium storage tank 34 through a recondenser 36. The helium gas storage system, which may be formed from one or more helium gas storage tanks 34 contains helium gas received as helium vapor from the cooling tubes 12 that removes heat from the magnet coils 20, 22 and forms part of the closed loop cooling system. The fluid communication between the recondenser 36 and the helium gas storage system 34 may be provided via one or more passageways 38.

The helium gas storage tanks 34 are in fluid communication with a cryorefrigerator 40 that includes the recondenser 36, which fluid communication may be provided via one or more fluid passageways 38. In various embodiments, the recondenser 36 may draw helium gas from the helium gas storage system 34 that operates to form a free convection circulation loop to cool the magnet coils 20, 22 and coil support shells 16, 18 to a cryogenic temperature, as well as fills the reservoir 24 with liquid helium via one or more passageways 44.

The cryorefrigerator 40, which may be a coldhead or other suitable cryocooler, extends through a cryostat and/or vacuum vessel 48 which contains therein the MRI magnet system 30 and the cooling components of the various embodiments. The cryorefrigerator 40 may extend within a sleeve or housing, referred to as coldhead sleeve 41. Thus, the cold end of the cryorefrigerator 40 may be positioned within the sleeve 41 without affecting the vacuum within the vacuum vessel. The cryorefrigerator 40 is inserted (or received) and secured within the sleeve using any suitable means, such as one or more flanges and bolts, or other suitable means. Moreover, a motor 50 of the cryorefrigerator 40 is provided outside the vacuum vessel and/or cryostat 48.

As illustrated in FIG. 2, the cryorefrigerator 40 in various embodiments includes the recondenser 36 at a lower end of the cryorefrigerator 40 that recondenses boiled off helium gas received from the vapor return manifold/passageway 32 in parallel with the helium gas storage system 34. The recondenser 36 allows for transferring boiled off helium gas from the helium gas storage system 34 to the liquid helium reservoir 24.

The magnet coils 20, which in various embodiments are molded coils, form a main superconducting magnet 52 that is controlled during operation of the MRI system as is known in the art to acquire MRI image data. Additionally, during operation of the MRI system, liquid helium travelling through the thermally coupled cooling tubes 12 cools the superconducting magnet 52. The superconducting magnet 52 may be cooled, for example, to a superconducting temperature, such as 4.2 Kelvin (K). The cooling process may include the recondensing of boiled off helium gas to liquid by the recondenser 36 and returned to the liquid helium tank 24, as well as cooling of the boiled off helium.

The various embodiments also provide a thermal shield 54, which may be in thermal contact with the helium gas storage system 34. The thermal shield 54 may be, for example, a thermally isolating radiation shield.

In an embodiment, rather than cooling via the circulation of liquid helium through cooling tubes that are thermally connected to the magnet or support shell, cooling may be provided by immersing the superconducting magnet coils in a bath of liquid helium, as is known in the art. In various embodiments, once cooled to operating temperature, the magnet coils may be cooled by thermal conduction and/or by thermosiphoning cooling. As will be readily appreciated, however, whether cooling is effected through the circulation of a liquid cryogen through a cooling loop that is in thermal communication with the magnet, or through the immersion of magnet coils in a bath of liquid cryogen, the coil formers/support structure, magnet coils and/or liquid cryogen reservoir form a cold mass 60 having a temperature of approximately 4.2 K, which provides for superconducting operations.

With further reference to FIGS. 1 and 2, the cooling system 10 for a superconducting magnet of the present invention further includes an auxiliary cooling device such as a thermal battery 62. The thermal battery 62 includes a compartment or enclosure 64 containing a high thermal capacity material 66. In an embodiment, the high thermal capacity material may be one or more of Gadolinium oxysulfide (GOS), Gadolinium Aluminum Perovskite (GAP) (GdAlO₃), holmium-copper (HoCu₂) and Lead (Pb), although other high thermal capacity materials may also be utilized without departing from the broader aspects of the present invention.

As illustrated in FIGS. 1-3 in an embodiment, the thermal battery 62 is coupled directly to the cold mass 60. For example, the thermal battery 62 may be directly attached to one of the coil formers 16, 18, the magnet 52 itself and/or to the liquid cryogen reservoir 24. In an embodiment, the material 66 of the thermal battery 62 may be lead and the thermal battery 62 may be immersed in liquid helium, such as in the liquid cryogen reservoir 24.

In operation, the thermal battery 62 is cooled during magnet cool down to substantially the same temperature as the cold mass 60 to which it is attached via the direct connection between the thermal battery 62 and the cold mass 60. In particular, as the liquid helium circulating within cooling tubes 12 cools down the coil formers 16, 18 and magnet coils 20, 22 in the manner discussed above, heat is also removed from the thermal battery material 66 until the thermal battery 62 is at the same temperature as the coil formers 16, 18 and magnet coils 20, 22, i.e., until they are in thermal equilibrium, at approximately 4.2 K. When the primary cooling loop 14 is unable to provide primary cooling, i.e., ride-through, the temperature of the magnet 52 will gradually rise due to heat leak. The thermal battery 62, however, is able to absorb some of this heat, thereby slowing the speed at which the magnet 52 warms and effectively extending the ride-through time. As will be readily appreciated, because the high thermal capacity material 66 stores cold energy during cool down, which is used to absorb heat during ride-through, the material 66 essentially functions as a thermal battery.

Turning now to FIG. 4, a cooling system 100 for a superconducting magnet illustrating the placement of a thermal battery according to another embodiment of the present invention is shown. The cooling system 100 is substantially identical to the cooling system 10 of FIGS. 1-3 in all respects, except for the particular location of the thermal battery 62. As illustrated in the simplified block diagram of FIG. 4, in an embodiment, the thermal battery 62 may be attached or coupled directly to the thermal shield 54 adjacent to the coldhead sleeve 41. In an embodiment, the thermal battery material may be one or more of Solid Nitrogen (SN2) and Lead (Pb), although other materials having a high thermal capacity such as Solid Neon (SNe), Solid Argon (SAr), Silver (Ag) and Copper (Cu) may also be utilized without departing from the broader aspects of the present invention. In operation, the thermal battery 62 may be cooled in the same manner discussed above in connection with FIGS. 1-3, namely, by conduction with the thermal shield 54 that is cooled through the circulation of liquid helium through cooling tubes. In an embodiment, the thermal shield 54 may be cooled by other methods known in the art, such as by a separate cooling loop.

When the coldhead 40 is deactivated or experiences a power interruption, the coldhead 40 and the coldhead sleeve 41 may be a heating source for the magnet coils and other components of the machine 30 due to heat leak from outside the machine 30. In particular, copper connections from the first stage of the sleeve 41 to the thermal shield 54 conductively transfer heat to the thermal shield 54. That is, the coldhead 40 may be a heat source when power is switched off, but the sleeve 41 is the main heat source when the coldhead 40 is taken out of the sleeve 41 for exchange, etc.). In addition, the thermal shield 54 will absorb heat from the vacuum vessel. This can cause the thermal shield 54 to warm, which can lead to heat leak from the thermal shield 54 to the cold mass 60, and ultimately to the magnet coils thereof, resulting in magnet warming.

The thermal battery 62 that is directly attached to the thermal shield 54 adjacent to the coldhead sleeve 41, however, can absorb heat from both the sleeve 41 and the thermal shield 54 itself, which will slow down the rate at which the thermal shield 54 warms. In particular, the thermal battery 62 substantially decreases the heat leak to the thermal shield 54 from the sleeve 41 by absorbing this heat. This, in turn, slows the speed at which the cold mass 60 and, in particular, the magnet 52 warms, effectively extending the ride-through time. Indeed, using the thermal battery 62 to limit the thermal shield temperature can effectively decrease the incremental heat leak to the cold mass 60 and gaseous helium storage tank 34, thereby increasing ride-through.

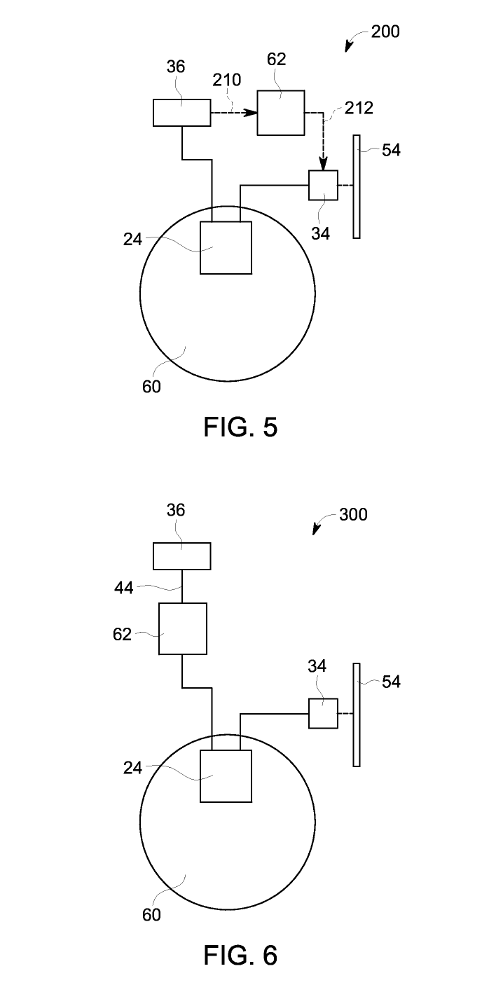

Turning now to FIG. 5, a cooling system 200 for a superconducting magnet according to another embodiment of the present invention is shown. The cooling system 200 is substantially identical to the cooling system 10 of FIGS. 1-3 in all respects, except for the particular location of the thermal battery 62. As illustrated in the simplified block diagram of FIG. 5, in an embodiment, the thermal battery 62 may be semi-coupled between the recondenser 36 of the cryorefrigerator 40 and the gas storage tank 34. In particular, the battery 62 may be selectively coupled to the recondenser 36 via a weak link or switch 210 and to the gaseous helium storage tank by a thermal switch 212. In an embodiment, the thermal battery 62 may be a 4-50 K thermal battery having any type of high thermal capacity material(s) known in the art such as, for example, Gadolinium oxysulfide (GOS), Gadolinium Aluminum Perovskite (GAP) (GdAlO₃), HoCu₂, SN₂, Lead, SNe, SAr, Silver and Copper and water ice.

The battery 62 is configured to transfer cooling power to the gaseous helium storage tank 34 during ride-through, thereby lowering the temperature and pressure within the tank 34 and/or slowing the warmup speed thereof. Lowering of the pressure within the tank 34 (as a result of lowering the temperature therewithin) causes helium gas transfer from the liquid reservoir 24 to the gas tank 34 as the system achieves a pressure balance. This helps decrease the pressure within the cooling system 200, as a whole, or at least decreases the rate at which system pressure builds, thereby increasing the ride-through time. Indeed, the thermal battery 62 is utilized to slow down the closed-loop system pressure that builds up as a result of the increase in temperature due to a power off condition or coldhead changeout by cooling down the gas tank 34, which makes the saturated cryogen temperature lower than its normal condition, resulting in longer ride-through.

With reference to FIG. 6, a cooling system 300 for a superconducting magnet according to another embodiment of the present invention is shown. The cooling system 300 is substantially identical to the cooling system 10 of FIGS. 1-3 in all respects, except for the particular location of the thermal battery 62. As illustrated in the simplified block diagram of FIG. 6, in an embodiment, the thermal battery 62 may be attached to the recondenser 36 of the coldhead 40 or to the conduit or passageway leading from the recondenser 36 to the liquid cryogen storage tank 24.

When the coldhead 40 is deactivated or removed for service or changeout, or experiences a power interruption, the recondenser 36 may experience a temperature increase due to heat leak along the coldhead 40 and sleeve 41. In certain situations, the recondenser 36 may even reach room temperature. The higher the temperature of the recondenser 36, the more heat is being transferred from the recondenser 36 to the liquid cryogen storage tank 24. This can ultimately leads to warming of the magnet 52 and quenching which, as discussed above, is undesirable.

The thermal battery 62 of the cooling system 300, however, limits the heat leak to the liquid cryogen storage tank 24 when the coldhead 40 is off by absorbing the heat that is leaked from the recondenser 36 and/or coldhead sleeve 41 and preventing it from being directly conductively transferred to the liquid cryogen storage tank 24. In particular, the battery 62 absorbs the heat via its conductive connection with the recondenser 36 or the conduit 44 leading from the recondenser 36 to the liquid cryogen storage tank 24. Accordingly, by slowing the heat transfer to the tank 24, the temperature rise in the tank 24 and the temperature rise in cold mass 60, including the magnet 52, can be slowed, thereby increasing the ride-through time.

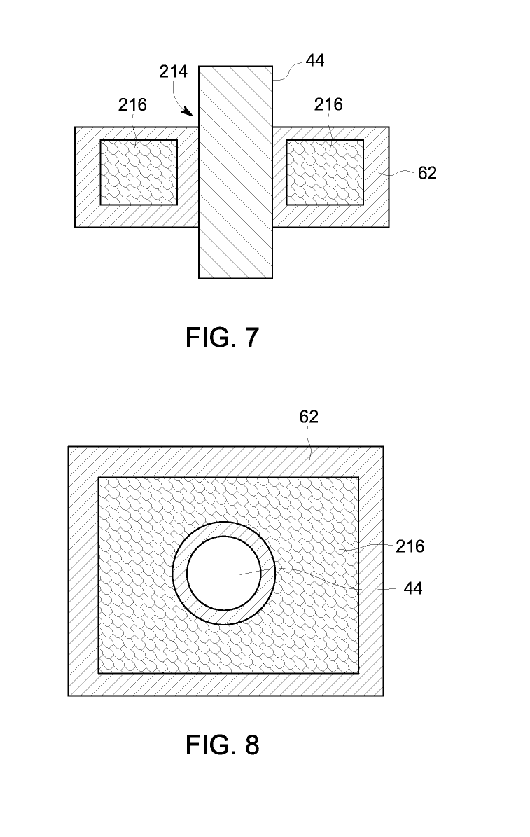

As illustrated in FIGS. 7 and 8, the thermal battery 62 of the cooling system 300 may be conductively coupled to the stainless-steel conduit or passageway 44 leading from the recondenser 36 to the liquid cryogen storage tank 24 as discussed above. In particular, a conductive interface 214 may be formed between the thermal battery 62 and the passageway 44 through brazing. As also illustrated in FIGS. 7 and 8, the thermal battery 62 may include a foam metal material 216 such as aluminum foam or porous sintered metal structures. In an embodiment, the pores within the foam metal material 216 may be filled with gaseous nitrogen or helium, which may enhance thermal transfer.

With further reference to the configuration of the cooling system 300 illustrated in FIG. 6, the thermal battery 62 is utilized as an anchor to decrease heat leak to the cold mass 60 (including to the magnet 52) when the cooling source location becomes warm, which can effectively increase the ride-through time when thermal mass is the same.

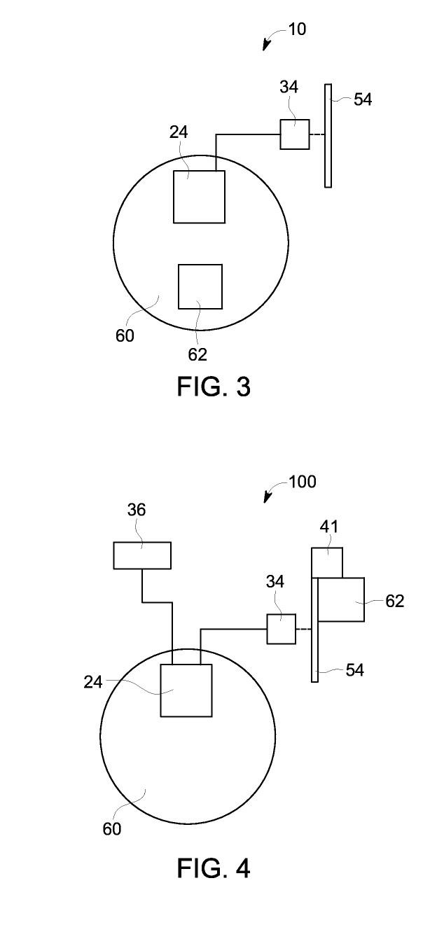

In connection with the above-described embodiments, the high thermal capacity material 66 of the thermal battery 62 may be a solid, liquid or gas at room temperature. With particular respect to the embodiments illustrated in FIGS. 3 and 4, it is desired that the interface between the cold mass 60 and the thermal battery 62 has high thermal conductivity. In connection with this, when affixing the thermal battery 62 to a solid surface, such as a surface of the cold mass 60, the interface therebetween may be established via a mechanical connection. In an embodiment, conductive materials such as, for example, epoxy or grease, may be interposed between the respective surfaces to increase the conductive connection therebetween. In an embodiment, the high thermal capacity material 66 may be mixed with a thermally conductive epoxy to yield a solid part. In embodiment, the high thermal capacity material 66 may be mixed with conductive grease and packed into enclosure 64. The enclosure 64 may then be mechanically coupled to the cold mass 60 in the manner hereinbefore described to provide an interface having high thermal conductivity.

In connection with the above, where the thermal battery 62 contains a liquid at room temperature for use as the high thermal capacity material 66, when filling the enclosure 64 with the liquid, room may be left within the enclosure 64 for possible expansion. Where the high thermal capacity material is a gas at room temperature (e.g., nitrogen), the enclosure 64 may include a burst disc or safety valve (not shown) that is configured to open when the pressure inside the enclosure 64 reaches a threshold level.

As discussed above, superconducting magnets must be maintained at a low temperature and be safely energized without quench even when there is no cooling power due to power failure, cryocooler service or changeout or cryocooler failure. For closed-loop, low cryogen magnets, the very little cryogen utilized in the primary cooling loop only allows for a short ride-through time in comparison to traditional magnet cooling systems. During facility power failure, the coldhead is in position, so the coldhead sleeve typically will not experience a dramatic temperature rise. During coldhead exchange, however, after the coldhead is removed the sleeve may warm rapidly, leading to an extremely short ride-through period and increasing the risk of magnet quench.

The present invention therefore provides a cooling system for a low cryogen superconducting magnet (LCM) that utilizes a thermal battery to maintain the magnet at low temperature to prevent quench, and to therefore extend ride-through time, during an interruption in primary cooling. The interruption in primary cooling may occur because of a power interruption to or within a facility, or due to a faulty coldhead, as well as during coldhead changeout or scheduled maintenance. Providing a longer ride-through period can therefore offer a larger window of time to solve the issue that resulted in the loss of cooling power or to swap the coldhead, which can decrease the risk of magnet warmup and quench. Various ways of decreasing the warmup rate of the magnet and/or maintaining the magnet at low temperature are envisioned by the various embodiments described above including, for example, increasing the thermal mass of the system or decreasing heat, and for a system that utilizes saturated liquid to maintain temperature, controlling the saturated pressure.

In particular, the various embodiments of the present invention described above contemplate using a high thermal capacity material as a thermal battery to store cold energy during normal magnet cool-down and during normal working operation. When the primary cooling means is interrupted or fails, the thermal battery can absorb heat from system components directly or indirectly, thereby slowing the warm-up rate of the magnet coils, allowing for longer ride-through time. Indeed, in certain embodiments a thermal battery may be utilized to directly cool the cold mass including the magnet coils, coil formers and/or cryogen reservoir when primary cooling is interrupted, i.e., to provide direct auxiliary cooling of the superconducting magnet to prevent quench. In other embodiments, a thermal battery may be utilized in an ‘indirect’ manner to prevent the leak of heat to the cold mass and superconducting magnet when primary cooling is interrupted. In particular, rather than cooling the cold mass directly, the thermal battery may be utilized to absorb heat from other system components to prevent or minimize the heat leakage from such components to the cold mass, which could otherwise result in magnet quench.

While the embodiments described above contemplate the use of a thermal battery to directly or indirectly prevent or slow the temperature rise in a superconducting magnet, the present invention is not limited to any single implementation. Indeed, it is contemplated that the various embodiments described above may be utilized in conjunction with one another to provide a combination of direct and indirect heat absorption to directly and/or indirectly prevent or slow the temperature rise in a magnet. In particular, it is envisioned that an imaging device may contain a plurality of thermal batteries coupled to various components of the imaging device such as, for example, to cool the cold mass and/or thermal shield directly, as well as for coupling with a recondenser, coldhead sleeve, gas storage tank, etc. to minimize heat leak to the cold mass. In addition, while the embodiments described above have been described in connection with conduction-cooled or thermosiphon-cooled systems that utilize a supply of liquid and a recondenser to cool the magnet coils, it is envisioned that the present invention may be equally applicable to pure conduction cooled systems that do not utilize liquid helium.

In an embodiment, a cooling system for a low-cryogen superconducting magnet is provided. The cooling system includes a primary cooling loop having a liquid reservoir containing a supply of liquid cryogen and a plurality of cooling tubes fluidly coupled to the liquid reservoir and in thermal communication with the superconducting magnet. The liquid cryogen is configured for circulation through the cooling tubes for providing primary cooling for the magnet for cooling the magnet to a target temperature. The cooling system also includes a thermal battery coupled to a component that is cooled to the target temperature by the primary cooling loop and is configured to be cooled by the primary cooling and to absorb heat from the at least one component during an interruption in the primary cooling to maintain the magnet at approximately the target temperature. In an embodiment, the component is at least one of the superconducting magnet, a coil former configured to support a plurality of coils of the superconducting magnet, and the liquid reservoir. In an embodiment, the thermal battery includes a high thermal capacity material. The material may be at least one of gadolinium oxysulfide, gadolinium aluminum perovskite, HoCu₂, and lead. In an embodiment, the thermal battery is immersed in the liquid cryogen within the liquid reservoir. In an embodiment, the system also includes a thermal shield in thermal communication with a gas storage tank and a cryocooler having a recondenser fluidly coupled to the gas storage tank and the reservoir. The thermal battery may be coupled to the thermal shield. In an embodiment, the thermal battery includes a high thermal capacity material including at least one of solid nitrogen and lead. In an embodiment, the thermal battery may be configured to absorb heat from the gas storage tank and the thermal shield. In an embodiment, the cryogen is liquid helium. In an embodiment, the target temperature is approximately 4 Kelvin.

In an embodiment, a cooling system for a low-cryogen superconducting magnet is provided. The system includes a primary cooling loop having a cryogen configured for circulation therethrough. The first cooling loop is in thermal communication with a cold mass and is configured to cool the cold mass to a target temperature. The cold mass includes at least one of a coil of the superconducting magnet, a support shell for supporting the coil, and a liquid reservoir containing the cryogen. The system also includes a cryocooler configured to cool the cryogen within the primary cooling loop and a thermal battery configured absorb heat from at least one component other than the cold mass and to minimize heat leak from the component to the cold mass. In an embodiment, the system may also include a recondenser fluidly coupled to the liquid reservoir via a conduit. The thermal battery may be conductively coupled to at least one of the recondenser and the conduit and may be configured to minimize the heat leak from the recondenser to the liquid reservoir. In an embodiment, the thermal battery includes a foam metal and at least one of helium and nitrogen. In an embodiment, the cooling system may also include a recondenser fluidly coupled to the liquid reservoir and a gas storage tank fluidly coupled to the liquid reservoir through the recondenser. The thermal battery may be thermally connected to the recondenser through a first thermal switch and to the gas storage tank through a second thermal switch. In an embodiment, the thermal battery is configured to provide auxiliary cooling to the gas storage tank to decrease a cooling system pressure. In an embodiment, the thermal battery includes a high thermal capacity material including at least one of gadolinium oxysulfide, gadolinium aluminum perovskite, HoCu₂, lead, solid nitrogen, solid neon, solid argon, silver and copper. In an embodiment, the cryogen is liquid helium.

In another embodiment, a method of cooling a superconducting magnet of an imaging device is provided. The method includes the step of circulating a liquid cryogen through a cooling loop in thermal communication with a cold mass including at least one of a coil of the superconducting magnet, a coil support shell and a reservoir containing the liquid cryogen to cool the cold mass to a target temperature and, at a thermal battery, absorbing heat from the cold mass via conduction between the thermal battery and the cold mass. In an embodiment, the thermal battery includes a high thermal capacity material including at least one of gadolinium oxysulfide, gadolinium aluminum perovskite, HoCu₂ and lead. In an embodiment, the method may also include the step of, at the thermal battery, absorbing heat from a thermal shield via conduction between the thermal battery and the thermal shield.

In yet another embodiment, a method of cooling a superconducting magnet of an imaging device is provided. The method includes the steps of circulating a liquid cryogen through a cooling loop in thermal communication with a cold mass including at least one of a coil of the superconducting magnet, a coil support shell and a reservoir containing the liquid cryogen to cool the cold mass to a target temperature, and minimizing heat leak from a component of the imaging device to the cold mass by absorbing heat from the component utilizing a thermal battery. In an embodiment, the component is a coldhead sleeve of the imaging device. In an embodiment, the component is a gas storage tank. In an embodiment, the thermal battery includes a high thermal capacity material including at least one of gadolinium oxysulfide, gadolinium aluminum perovskite, HoCu₂, holmium-copper, lead, solid nitrogen, solid neon, solid argon, silver and copper. In an embodiment, the imaging device includes a recondenser fluidly coupled to the reservoir via a conduit. The thermal battery may be conductively coupled to at least one of the recondenser and the conduit and may be configured to minimize the heat leak from the recondenser to the reservoir.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope.

While the dimensions and types of materials described herein are intended to define the parameters of the invention, they are by no means limiting and are exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, terms such as “first,” “second,” “third,” “upper,” “lower,” “bottom,” “top,” etc. are used merely as labels, and are not intended to impose numerical or positional requirements on their objects. Further, the limitations of the following claims are not written in means-plus-function format and are not intended to be interpreted based on 35 U.S.C. §122, sixth paragraph, unless and until such claim limitations expressly use the phrase “means for” followed by a statement of function void of further structure.

This written description uses examples to disclose several embodiments of the invention, including the best mode, and also to enable one of ordinary skill in the art to practice the embodiments of invention, including making and using any devices or systems and performing any incorporated methods. The patentable scope of the invention is defined by the claims, and may include other examples that occur to one of ordinary skill in the art. Such other examples are intended to be within the scope of the claims if they have structural elements that do not differ from the literal language of the claims, or if they include equivalent structural elements with insubstantial differences from the literal languages of the claims.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

Since certain changes may be made in the above-described invention, without departing from the spirit and scope of the invention herein involved, it is intended that all of the subject matter of the above description or shown in the accompanying drawings shall be interpreted merely as examples illustrating the inventive concept herein and shall not be construed as limiting the invention.

What is claimed is:

1. A cooling system for a low-cryogen superconducting magnet, comprising:
a primary cooling loop having at least one liquid reservoir containing a supply of liquid cryogen and a plurality of cooling tubes fluidly coupled to the liquid reservoir and in thermal communication with the superconducting magnet, the liquid cryogen circulates through the cooling tubes for providing primary cooling for the magnet for cooling the magnet to a target temperature; and
at least one thermal battery coupled to a component that is cooled to the target temperature by the primary cooling loop, the thermal battery being configured to be cooled by the primary cooling and to absorb heat from the at least one component during an interruption in the primary cooling to maintain the magnet at approximately the target temperature.

2. The cooling system of claim 1, wherein:
the component is at least one of the superconducting magnet, a coil former configured to support a plurality of coils of the superconducting magnet, and the liquid reservoir.

3. The cooling system of claim 2, wherein:
the thermal battery includes a high thermal capacity material.

4. The cooling system of claim 3, wherein:
the material is at least one of gadolinium oxysulfide, gadolinium aluminum perovskite, HoCu₂ and lead.

5. The cooling system of claim 1, wherein:
the thermal battery is immersed in the liquid cryogen within the liquid reservoir.

6. The cooling system of claim 1, further comprising:
a thermal shield in thermal communication with a gas storage tank; and
a cryocooler having a recondenser fluidly coupled to the gas storage tank and the reservoir;
wherein the thermal battery is coupled to the thermal shield.

7. The cooling system of claim 6, wherein:
the thermal battery includes a high thermal capacity material including at least one of solid nitrogen, water ice and lead.

8. The cooling system of claim 7, wherein:
the thermal battery is configured to absorb heat from the gas storage tank and the thermal shield.

9. The cooling system of 1, wherein:
the cryogen is liquid helium.

10. The cooling system of claim 1, wherein:
the target temperature is approximately 4 Kelvin.

11. A cooling system for a low-cryogen superconducting magnet, comprising:
a primary cooling loop having a cryogen for circulation therethrough, the first cooling loop being in thermal communication with a cold mass and configured to cool the cold mass to a target temperature, the cold mass including at least one of a coil of the superconducting magnet, a support shell for supporting the coil, and a liquid reservoir containing the cryogen;
a cryocooler configured to cool the cryogen within the primary cooling loop; and
a thermal battery configured to absorb heat from at least one component other than the cold mass and to minimize heat leak from the component to the cold mass.

12. The cooling system of claim 11, further comprising:
a recondenser fluidly coupled to the liquid reservoir via a conduit;
wherein the thermal battery is conductively coupled to at least one of the recondenser and the conduit and is configured to minimize the heat leak from the recondenser to the liquid reservoir.

13. The cooling system of claim 12, wherein:
the thermal battery includes a foam metal and at least one of helium and nitrogen.

14. The cooling system of claim 11, further comprising:
a recondenser fluidly coupled to the liquid reservoir; and
a gas storage tank fluidly coupled to the liquid reservoir through the recondenser;
wherein the thermal battery is thermally connected to the recondenser through a first thermal switch and to the gas storage tank through a second thermal switch.

15. The cooling system of claim 14, wherein:
the thermal battery is configured to provide auxiliary cooling to the gas storage tank to decrease a cooling system pressure.

16. The cooling system of claim 15, wherein:
the thermal battery includes a high thermal capacity material including at least one of gadolinium oxysulfide, gadolinium aluminum perovskite, HoCu₂, lead, solid nitrogen, solid neon, solid argon, silver and copper.

17. The cooling system of claim 11, wherein:
the cryogen is liquid helium.

18. A method of cooling a superconducting magnet of an imaging device, the method comprising the steps of:
circulating a liquid cryogen through a cooling loop in thermal communication with a cold mass including at least one of a coil of the superconducting magnet, a coil support shell and a reservoir containing the liquid cryogen to cool the cold mass to a target temperature; and
at a thermal battery, absorbing heat from the cold mass via conduction between the thermal battery and the cold mass.

19. The method according to claim 18, wherein:
the thermal battery includes a high thermal capacity material including at least one of gadolinium oxysulfide, gadolinium aluminum perovskite, HoCu₂ and lead.

20. The method according to claim 18, further comprising the step of:
at the thermal battery, absorbing heat from a thermal shield via conduction between the thermal battery and the thermal shield.

21. A method of cooling a superconducting magnet of an imaging device, the method comprising the steps of:
circulating a liquid cryogen through a cooling loop in thermal communication with a cold mass including at least one of a coil of the superconducting magnet, a coil support shell and a reservoir containing the liquid cryogen to cool the cold mass to a target temperature; and
minimizing heat leak from a component of the imaging device to the cold mass by absorbing heat from the component utilizing a thermal battery.

22. The method according to claim 21, wherein:
the component is a coldhead sleeve of the imaging device.

23. The method according to claim 21, wherein:
the component is a gas storage tank.

24. The method according to claim 21, wherein:
the thermal battery includes a high thermal capacity material including at least one of gadolinium oxysulfide, gadolinium aluminum perovskite, HoCu₂, holmium-copper, lead, solid nitrogen, solid neon, solid argon, silver and copper.

25. The method according to claim 21, wherein:
the imaging device includes a recondenser fluidly coupled to the reservoir via a conduit;
wherein the thermal battery is conductively coupled to at least one of the recondenser and the conduit and is configured to minimize the heat leak from the recondenser to the reservoir.
